(19) United States
(12) Patent Application Publication
(10) Pub. No.: US 2006/0090105 A1
(43) Pub. Date: Apr. 27, 2006

(54) Built-in self test for read-only memory including a diagnostic mode

(76) Inventor: Paul R. Woods, Corvallis, OR (US)

Correspondence Address: AGILENT TECHNOLOGIES, INC.;INTELLECTUAL PROPERTY ADMINISTRATION, LEGAL DEPT., P.O. BOX 7599, M/S DL429, LOVELAND, CO, 80537-0599, US

(21) Appl. No.: 10/974,084

(22) Filed: Oct. 27, 2004

(51) Int. Cl. G11C 29/00

(52) U.S. Cl. 714/718

(57) ABSTRACT

A semiconductor circuit comprises a read-only memory (ROM), and a built-in self test (BIST) circuit coupled to the ROM. The BIST circuit is configured to output an entire contents of the ROM.

### BACKGROUND

Read-only memories (ROMs) are used in many systems for storing bootstrap code for initializing the systems when the systems are powered on or reset. A single bit defect in a ROM can cause a processor to execute an unintended instruction and lead to a boot failure of the system. A common method for determining that there are no bit altering defects in a ROM is a built-in self test (BIST). Typically, BISTs use signature analysis to determine if the ROMs have defects. After analyzing the results of the signature analysis, BISTs provide an output indicating a pass or fail value. Typically, however, BISTs do not provide any indication of what bit or bits caused a failure of the ROM.

Signature analysis is used to determine if a ROM has defects. A ROM holds a stream of data that can be reduced to a unique code or signature that represents the stream of data held in the ROM. By comparing the unique code or signature of the ROM to a previously determined golden (desired) signature for the ROM, a pass/fail value indicating whether the ROM has defects can be generated. If the unique code or signature of the ROM is the same as the previously determined golden signature, then the ROM is very likely free of defects and a pass value is generated. If the unique code or signature of the ROM is different than the previously determined golden signature, then the ROM has defects and a fail value is generated.

### SUMMARY

One aspect of the present invention provides a semiconductor circuit. The semiconductor circuit comprises a read-only memory (ROM), and a built-in self test (BIST) circuit coupled to the ROM. The BIST circuit is configured to output an entire contents of the ROM.

### BRIEF DESCRIPTION OF THE DRAWINGS

FIG. 1 is a block diagram illustrating one embodiment of a semiconductor circuit including a read-only memory (ROM) and a built-in self test (BIST).

FIG. 2 is a diagram illustrating one embodiment of the semiconductor circuit of FIG. 1 in more detail.

FIG. 3 is a flow diagram illustrating one embodiment of a method for outputting the entire contents of a ROM in a diagnostic mode.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following Detailed Description, therefore, is not to be taken in a limiting sense, and the scope of the present invention is defined by the appended claims.

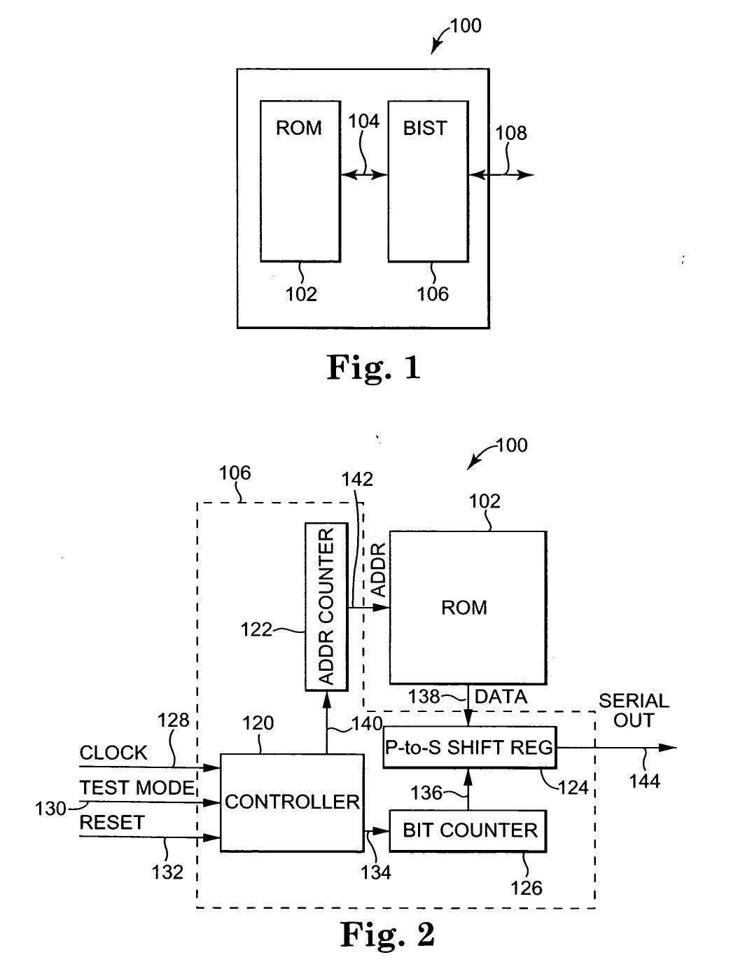

FIG. 1 is a block diagram illustrating one embodiment of a semiconductor circuit 100 including a read-only memory (ROM) 102 and a built-in self test (BIST) 106. ROM 102 is electrically coupled to BIST 106 through communication link 104. BIST 106 has an I/O interface 108 for controlling the functionality of BIST 106 and for outputting test results. I/O interface 108 can be coupled to a host device, which provides inputs to BIST 106 to perform built-in self tests, such as signature analysis, on ROM 102 or to perform diagnostics, such as outputting the entire contents of ROM 102. In one embodiment, BIST 106 is configured to receive a diagnostic command on I/O interface 108, and in response to the diagnostic command, output the entire contents of ROM 102 serially via I/O interface 108 to the host device for analysis. In one embodiment, semiconductor circuit 100 can include other components, such as a processor.

FIG. 2 is a block diagram illustrating one embodiment of semiconductor circuit 100 in more detail. Semiconductor circuit 100 includes ROM 102, controller 120, address counter 122, parallel to serial (P-to-S) shift register 124, and bit counter 126. Controller 120, address counter 122, parallel to serial shift register 124, and bit counter 126 are part of BIST 106. Controller 120 receives a clock signal on clock signal path 128, a test mode signal on test mode signal path 130, and a reset signal on reset signal path 132. Controller 120 is electrically coupled to address counter 122 through path 140 and to bit counter 126 through path 134. Address counter 122 is electrically coupled to ROM 102 through address path 142. Bit counter 126 is electrically coupled to parallel to serial shift register 124 through path 136. Parallel to serial shift register 124 is electrically coupled to ROM 102 through data path 138. Parallel to serial shift register 124 provides serial output data on serial out data path 144.

ROM 102 is a non-volatile memory, such as an embedded ROM (embedded ROM), or other suitable ROM memory. In one embodiment, ROM 102 is a boot ROM for storing bootstrap code for initializing a system when the system is powered on or reset. In one embodiment, ROM 102 is a 32 kbyte ROM including 32-bit words. Address counter 122 provides an address on address path 142 to address a word of ROM 102. ROM 102 outputs the addressed word on data path 138 to parallel to serial shift register 124. Parallel to serial shift register 124 receives the addressed word from ROM 102 in parallel. Parallel to serial shift register 124 outputs the addressed word from ROM 102 serially on serial out data path 144. In one embodiment, parallel to serial shift register 124 is a multiple input signature register (MISR). MISR 124 is used to provide a signature for ROM 102 in a signature analysis mode. Bit counter 126 controls parallel to serial shift register 124 to shift the bits of the addressed word or signature out of parallel to serial shift register 124. Controller 120 controls address counter 122 and bit counter 126 based on inputs on clock signal path 128, test mode signal path 130, and reset signal path 132.

In operation, controller 120 receives a clock signal on clock signal path 128, a test mode signal on test mode signal path 130, and/or a reset signal on reset signal path 132. In one embodiment, there are four test modes. The four test modes include a normal mode or no testing mode, a form signature mode, a shift out signature mode, and a diagnostic or shift out entire ROM contents mode. In one embodiment, the normal mode is indicated by a “00” input value, the form signature mode is indicated by a “01” input value, the shift out signature mode is indicated by a “10” input value, and the diagnostic mode is indicated by a “11” input value.

In response to a form signature mode signal, controller 120 controls address counter 122 and bit counter 126 to form the signature of the contents of ROM 102 in parallel to serial shift register 124. In response to a shift out signature mode signal, controller 120 controls bit counter 126 to shift the signature out of parallel to serial shift register 124. In some embodiments, circuitry in BIST 106 performs signature analysis. The signature analysis can be performed using one of a number of signature analysis techniques, a few of which are described below.

In one embodiment, the signature analysis is similar to a technique called Cyclic Redundancy Checking (CRC), which is used to determine if a stream of bits has been transmitted free of errors. In CRC, a CRC code is generated on the transmitting side for the stream of bits to be transmitted. Once the stream of bits has been transmitted, the transmitter transmits the CRC code. Using the same CRC algorithm as the transmitter, the receiver generates its own CRC code on the stream of bits received and compares it to the transmitted CRC code. If the codes match, it is very likely that the stream of bits was transmitted free of errors. If the codes do not match, the stream of bits was transmitted with errors. ROM 102 holds a stream of data. But in this case, rather than attempting to detect transmission errors, the CRC code is used to determine if there are manufacturing defects in ROM 102 that manifest as bit errors in the ROM 102 data image. In BIST applications, the CRC code is called the signature.

In another embodiment, the signature analysis uses the MD5 algorithm. The MD5 algorithm is a type of checksum commonly used to verify that a file has not changed due to errors or tampering. Even slight changes in a file cause the MD5 algorithm to produce a very different checksum. Even very large files in which only one bit has been changed produce very different golden and erroneous checksums. Because of the complexity of the MD5 algorithm, it would be virtually impossible to alter a file in a way that would produce the same MD5 checksum as the original. This property lends itself to the testing of ROM 102.

In another embodiment, the signature analysis is based on a division operation using the following Equation 1:
R(x)=P(x) mod G(x) Equation 1
where:
   P(x)=the data stream
   G(x)=the divisor
   R(x)=the remainder or signature

This function is performed using bit-stream algebra and parallel to serial shift register 124. In one embodiment, G(x)=x³¹+x²⁸+x²⁷+x+1. In other embodiments, other suitable divisors are used. In this embodiment, controller 120 receives a test mode signal on test mode signal path 130 indicating a form signature mode. Controller 120 then receives a reset signal on reset signal path 132 and a clock signal on clock signal path 128 to reset semiconductor circuit 100. Next, the signature is formed in parallel to serial shift register 124 in response to a clock signal on clock signal path 128. Once the signature is formed, controller 120 receives a test mode signal on test mode signal path 130 indicating a shift out signature mode. Controller 120 then shifts the signature out on serial out data path 144 in response to a clock signal on clock signal path 128.

In another embodiment, instead of reading out the signature, the signature is compared to a golden signature hard coded in a register in semiconductor circuit 100. In another form of the invention, the golden signature is stored in the last ROM 102 location. Instead of running the signature analysis on the entire ROM 102, the signature analysis is run on all but the last ROM 102 location and compared to the golden signature stored in the last ROM 102 location. In another embodiment, a value is stored in the last ROM 102 location that causes the signature to become all zeros.

With a diagnostic mode signal on test mode signal path 130, and following a reset signal on reset signal path 132, controller 120 controls address counter 122 and bit counter 126 to output the entire contents of ROM 102 as described in further detail below.

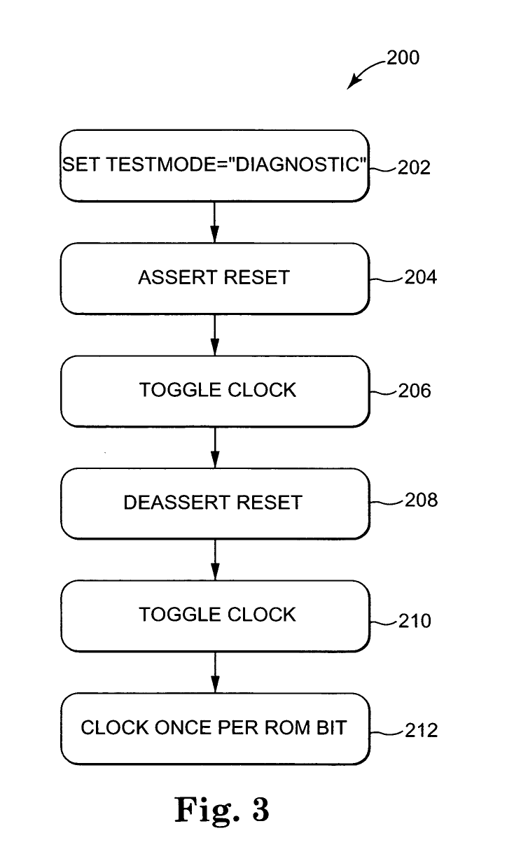

FIG. 3 is a flow diagram illustrating one embodiment of a method 200 for outputting the entire contents of ROM 102. At 202, controller 120 receives a test mode signal on test mode signal path 130 indicating a diagnostic or a shift out entire contents of ROM 102 mode. At 204, controller 120 receives an asserted reset signal on reset signal path 132. At 206, controller 120 receives a clock signal on clock signal path 128. In response to the clock signal, controller 120 resets address counter 122 to the first word of ROM 102 and resets bit counter 126 to the first bit of the word to prepare for outputting the contents of ROM 102. At 208, the reset signal on reset signal path 132 is deasserted. At 210, controller 120 receives a clock signal on clock signal path 128. In response to the clock signal, controller 120 initiates address counter 122 and bit counter 126 to begin outputting the contents of ROM 102. At 212, the clock signal on clock signal path 128 is toggled one time for each bit in ROM 102. Each toggle of the clock signal on clock signal path 128 outputs a single bit of ROM 102 on serial out data path 144.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor circuit comprising:
a read-only memory (ROM); and
a built-in self test (BIST) circuit coupled to the ROM, the BIST circuit configured to output an entire contents of the ROM.

2. The semiconductor circuit of claim 1, wherein the BIST circuit is configured to serially output the entire contents of the ROM.

3. The semiconductor circuit of claim 1, wherein the BIST circuit comprises a parallel to serial shift register coupled to the ROM, the parallel to serial shift register adapted to receive one word of the ROM in parallel and output the word serially.

4. The semiconductor circuit of claim 3, wherein the BIST circuit comprises a bit counter coupled to the parallel to serial shift register, the bit counter adapted to shift bits out of the parallel to serial shift register.

5. The semiconductor circuit of claim 4, wherein the BIST circuit comprises an address counter coupled to the ROM, the address counter adapted to address the ROM.

6. The semiconductor circuit of claim 5, wherein the BIST circuit comprises a controller coupled to the bit counter and the address counter, the controller configured to control the bit counter and the address counter to output the entire contents of the ROM.

7. The semiconductor circuit of claim 1, wherein the BIST circuit comprises a controller coupled to the ROM, the controller configured to receive a clock signal, a test mode signal, and a reset signal for controlling outputting the entire contents of the ROM.

8. The semiconductor circuit of claim 1, wherein the ROM comprises an embedded read-only memory.

9. The semiconductor circuit of claim 1, wherein the ROM comprises a boot ROM for storing bootstrap code for initializing a system when the system is powered on or reset.

10. The semiconductor circuit of claim 1, wherein the ROM comprises an at least 32 kbyte ROM having at least 32-bit words.

11. A semiconductor circuit comprising:
an embedded read only memory (embedded ROM); and
a built-in self test (BIST) for testing the embedded ROM, the BIST configured to serially output an entire contents of the embedded ROM based on an input indicating a diagnostic mode.

12. The semiconductor circuit of claim 11, wherein the BIST comprises a parallel to serial shift register coupled to the embedded ROM, the parallel to serial shift register adapted to receive a word of the embedded ROM in parallel and output the word serially.

13. The semiconductor circuit of claim 12, wherein the BIST comprises:
a controller;
an address counter coupled between the controller and the embedded ROM, the address counter adapted to address words of the embedded ROM; and
a bit counter coupled between the controller and the parallel to serial shift register, the bit counter adapted to control the parallel to serial shift register,
wherein the controller is adapted to control the address counter and the bit counter.

14. The semiconductor circuit of claim 11, wherein the BIST is configured to perform signature analysis on the embedded ROM.

15. A method of testing an embedded read-only memory (embedded ROM) comprising a built-in self test (BIST) circuit, the method comprising:
setting a test mode of the BIST circuit to a diagnostic mode for outputting an entire contents of the embedded ROM;
resetting the BIST circuit; and
outputting the entire contents of the embedded ROM.

16. The method of claim 15, wherein resetting the BIST circuit comprises resetting an address counter to address a first word in the embedded ROM.

17. The method of claim 15, wherein resetting the BIST circuit comprises resetting a bit counter to address a first bit of a word from the embedded ROM.

18. The method of claim 15, wherein resetting the BIST circuit comprises:
asserting a reset signal to a first input of the BIST circuit;
toggling a clock signal input of the BIST circuit; and
deasserting the reset signal to the first input of the BIST circuit.

19. The method of claim 15, wherein outputting the entire contents of the embedded ROM comprises serially outputting the entire contents of the embedded ROM.

20. The method of claim 15, wherein outputting the entire contents of the embedded ROM comprises toggling a clock signal input of the BIST circuit to output each bit from the embedded ROM.
